(19) United States
(12) Patent Application Publication
(10) Pub. No.: US 2011/0233716 A1
(43) Pub. Date: Sep. 29, 2011

(54) CIRCUIT STRUCTURE OF AN ULTRA HIGH VOLTAGE LEVEL SHIFTER

(75) Inventors: CHIEN-FU TANG, HSINCHU CITY (TW); ISAAC Y. CHEN, HSINCHU COUNTY (TW)

(73) Assignee: RICHTEK TECHNOLOGY CORP., HSINCHU (TW)

(21) Appl. No.: 13/048,057

(22) Filed: Mar. 15, 2011

(30) Foreign Application Priority Data
Mar. 26, 2010 (TW) 099109113

(51) Int. Cl. H01L 29/06

(52) U.S. Cl. 257/501; 257/E29.018

(57) ABSTRACT

A circuit structure of an ultra high voltage level shifter includes a low voltage substrate having the electronic elements of the ultra high voltage level shifter thereon, an ultra high voltage redistribution layer, and a passivation layer between the substrate and the redistribution layer to prevent dielectric breakdown between the redistribution layer and the substrate.

### FIELD OF THE INVENTION

The present invention is related generally to an ultra high voltage level shifter and, more particularly, to a circuit structure of an ultra high voltage level shifter.

### BACKGROUND OF THE INVENTION

As shown in FIG. 1, in application of a high side floating gate driver system 10, a high side transistor QH is connected to an ultra high voltage source Vin which may be up to 400V, and thus the phase node PHASE is switched between 0V and 400V during operation, for which it needs an ultra high voltage level shifter 12 to transfer the low voltage control signal PWM to ultra high voltage for driving the gate of the high side transistor QH. FIG. 2 is a circuit diagram of the ultra high voltage level shifter 12 shown in FIG. 1, which uses a pair of low voltage control signals Set and Reset switched between 0V and 12V to alternately switch MOSFETs Q1 and Q2, and with load resistors R1 and R2 connected to a boot terminal BOOT, produces high voltages V1 and V2 at the output terminals of the MOSFETs Q1 and Q2, in order to set and reset a latch 14 so as to generate a high voltage driving signal UG. As shown in FIG. 1, the boot terminal BOOT is connected to the phase node PHASE with a capacitor CBoot therebetween, and thus is switched between 12V and 412V during operation. Therefore, the voltages V1 and V2 shown in FIG. 2 may also reach 400V. In the physical circuit structure, as indicated by the broken line 16, there are high voltage traces between the low voltage and high voltage portions, and thus the dielectric from the high voltage trace to the substrate may breakdown when applying an ultra high voltage bias.

In further details, FIG. 3 is a cross-sectional view of the circuit structure around the MOSFET Q1 in a conventional integrated circuit. The connection between the MOSFET Q1 and the resistor R1 is implemented by a metal layer Metal1, on which the voltage V1 may reach 400V during operation, while the substrate where the MOSFET Q1 is formed is at a low voltage, typically the ground potential. Therefore, the voltage difference ΔV between the metal layer Metal1 and the substrate is close to 400V. When there is only a dielectric layer between the metal layer Metal1 and the substrate, as shown in FIG. 3, the structure may breakdown due to the high voltage difference ΔV.

U.S. Pat. No. 5,446,300 proposes a layout solution, which introduces a neck structure in the layout to overcome the high voltage problem. However, this solution disadvantageously increases the layout area, brings difficulty in calculation of the electric field, and tends to cause burnout of the connection circuit.

Therefore, it is desired a circuit structure of an ultra high voltage level shifter capable of enduring high voltage and easy to implement.

### SUMMARY OF THE INVENTION

An objective of the present invention is to provide a circuit structure of an ultra high voltage level shifter.

According to the present invention, a circuit structure of an ultra high voltage level shifter includes a low voltage substrate for the ultra high voltage level shifter to have its circuit elements formed thereon, an ultra high voltage redistribution layer (RDL), and a passivation layer between the substrate and the redistribution layer to prevent damage caused by the voltage difference between the substrate and the redistribution layer.

### BRIEF DESCRIPTION OF THE DRAWINGS

These and other objectives, features and advantages of the present invention will become apparent to those skilled in the art upon consideration of the following description of the preferred embodiments of the present invention taken in conjunction with the accompanying drawings, in which:

FIG. 1 is a circuit diagram of a high side floating gate driver system;

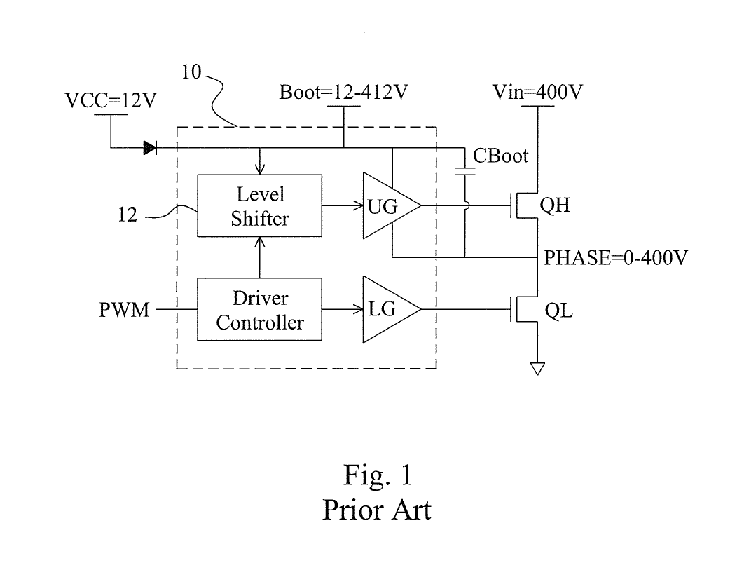

FIG. 2 is a circuit diagram of the ultra high voltage level shifter shown in FIG. 1;

FIG. 3 is a cross-sectional view of the circuit structure around the MOSFET of FIG. 2 in a conventional integrated circuit; and

FIG. 4 is a cross-sectional view of the circuit structure around the MOSFET of FIG. 2 in an integrated circuit according to the present invention.

### DETAILED DESCRIPTION OF THE INVENTION

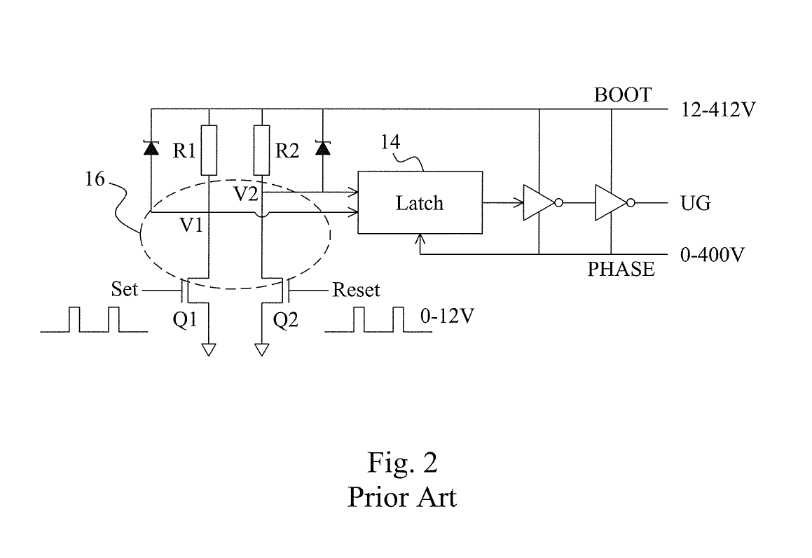

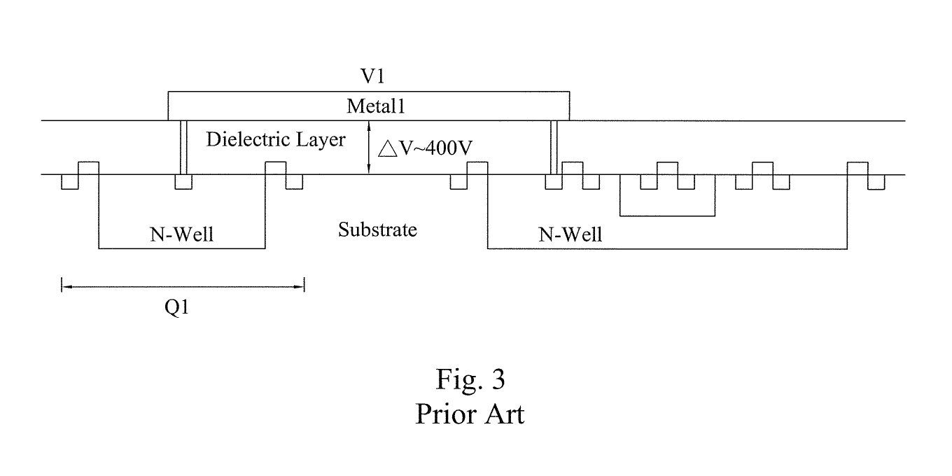

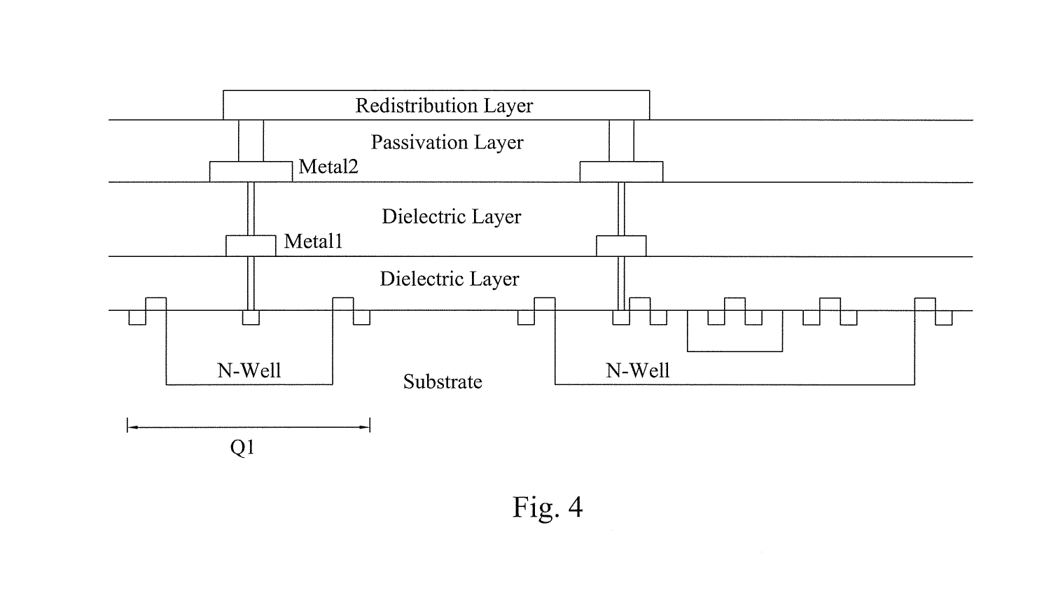

FIG. 4 is a cross-sectional view of the circuit structure around the MOSFET Q1 of FIG. 2 in an integrated circuit according to the present invention, which is different from the structure shown in FIG. 3 in that a redistribution layer is used as a bridge to replace the original metal layer for the connection between the MOSFET Q1 and the resistor R1. Conventionally, a redistribution layer is for wire routing and covers on the passivation of a chip in order to rearrange contacts to facilitate the subsequent packaging process. The present invention lays all the circuit parts receiving high voltage in the redistribution layer, so as to take those circuit parts receiving high voltage away from the substrate. In addition, a passivation layer that serves for electrical isolation is provided between the redistribution layer and the substrate, so as to further prevent any damage caused by the voltage difference between the substrate and the redistribution layer. Furthermore, the solution provided by the present invention can be easily achieved and realized through a simple silicide process.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A circuit structure of an ultra high voltage level shifter, comprising:
a low voltage substrate having circuit elements of the ultra high voltage level shifter thereon;
an ultra-high voltage redistribution layer; and
a passivation layer between the substrate and the redistribution layer for preventing damage caused by a voltage difference between the substrate and the redistribution layer.

2. The circuit structure of claim 1, wherein the substrate is grounded.
